(19) United States
(12) Patent Application Publication
(10) Pub. No.: US 2025/0176356 A1
(43) Pub. Date: May 29, 2025

(54) METHOD FOR PREPARING PIXEL DEFINE LAYER

(71) Applicant: DUK SAN NEOLUX CO., LTD., Cheonan-si (KR)

(72) Inventors: Jun BAE, Cheonan-si (KR); Kyung Soo KIM, Cheonan-si (KR); Changmin LEE, Cheonan-si (KR); Yeon Soo LEE, Cheonan-si (KR); Jin Hyun KIM, Cheonan-si (KR); Ju Cheol KWON, Cheonan-si (KR); Hak Young LEE, Cheonan-si (KR); Soung Yun MUN, Cheonan-si (KR)

(73) Assignee: DUK SAN NEOLUX CO., LTD., Cheonan-si (KR)

(21) Appl. No.: 18/958,909

(22) Filed: Nov. 25, 2024

(30) Foreign Application Priority Data
Nov. 24, 2023 (KR) 10-2023-0164968

(51) Int. Cl. H10K 59/12; H10K 59/122; H10K 71/40; H10K 85/10

(52) U.S. Cl. CPC H10K 59/1201; H10K 59/122; H10K 71/40; H10K 85/111

(57) ABSTRACT

Provided is a display having vivid colors, improved reliability, and lifespan by implementing a colored pattern having high optical density on an electrode substrate, wherein the optical density after completion of post-baking treatment process is increased using a colorant, a pigment dispersion having a size of 100 nm or less is used to reduce roughness, the pixel separation layer enables implementation of a flexible display and reduces the thickness and weight of the display, the visibility can be increased by blocking and absorbing external reflected light, and the hardness and modulus can be improved to the level of conventional pixel separation layers, thereby capable of implementing a display that does not generate cracks even when subjected to external impact, and a colored pattern with high optical density is realized on an electrode substrate, improving not only the vividness of the color but also impact resistance, reliability, and lifespan of the display.

### FIELD OF TECHNOLOGY

The present disclosure relates to a method for preparing a pixel defining layer of a light-emitting display device using a photosensitive composition.

### BACKGROUND OF ART

As a flat panel display device, a liquid crystal display device (LCD), an organic light-emitting display device (OLED), etc. are widely used. Among these, the organic light-emitting display device has advantages such as low power consumption, a fast response speed, high color reproducibility, high luminance, and a wide viewing angle.

In the case of the organic light-emitting display device, a polarizing film is used to block the light being reflected from the panel when external light is incident, and there is a disadvantage in that the polarizing film is not suitable for application to a flexible device due to a lack of bending properties.

As a method for solving the above problem, methods such as forming an inorganic film for blocking light on an upper substrate as well as a color filter and a black matrix have been proposed. However, these methods have limitations in obtaining a desired level of antireflection effect, and no specific methods for replacing the polarizing film have yet been suggested.

Coloring patterns, as red, green, and blue color filters, are being used not only in liquid crystal displays but also in organic light-emitting displays.

In preparing the above-mentioned coloring pattern, various types of organic pigments as well as carbon black and inorganic pigments are used as colorants, and a pigment dispersion in which these are dispersed is mixed with other compositions to form a pattern.

In such a pattern, the higher the optical density (OD) to block externally transmitted light or light reflected from below, the more excellent the visibility, and organic light-emitting displays made by pixels formed in this way can implement more vivid colors. However, as the particles of inorganic pigments used in the coloring pattern become larger, the visibility becomes reduced due to residues of the pattern, low optical density, and high roughness, thereby causing a decrease in luminance reliability.

Additionally, in such a pattern, the higher the optical density (OD) to block externally transmitted light or light reflected from below, the more excellent the visibility, and organic light-emitting displays made by pixels formed in this way can implement more vivid colors.

However, when the content of organic pigments used is low, the sintering hardness is low and cracks may occur due to external impact, whereas when the content of organic pigments is increased to enhance the sintering hardness, residues may be generated and dark spots may appear on the panel. For this reason, there is a need to develop a method to effectively increase the optical density around 550 nm, which has the most significant impact on visibility and improves sintering hardness.

### SUMMARY OF INVENTION

### Objective

In order to solve the problems of the related art, one embodiment of the present disclosure aims to implement an organic light-emitting display having high optical density and low roughness while reducing pattern residues during pattern deposition on a film by controlling the size of inorganic pigments, so as to not only have vivid colors but also increase reliability and lifespan of the display.

Additionally, the present disclosure also aims to provide a method for preparing a pixel defining layer capable of improving visibility by increasing the optical density near the 550 nm wavelength that has the most significant effect on visibility, thereby improving sintering hardness and modulus, and a pixel defining layer prepared thereby.

Another embodiment aims to provide an organic light-emitting display device including a pixel defining layer prepared by the above method.

Still another embodiment aims to provide an electronic device including the organic light-emitting display device.

### Solution

The method for preparing a pixel defining layer of the present disclosure is a method which includes the steps of: applying and coating a photosensitive composition including a colorant having an average pigment particle size of 120 nm or less; performing prebaking; performing exposure; performing development; and performing post-baking treatment, and it is preferable that after the post-baking treatment step, the coating film has an optical density of 0.80/μm to 2.0/μm, a sintering hardness of 350 N/mm² to 470 N/mm², a modulus of 5,200 Mpa to 6,800 Mpa, and a roughness of 3.0 nm or less, and has no residue.

It is preferable that the pigment has an average particle size of 110 nm, and preferably 100 nm or less.

It is preferable that the temperature of the post-baking treatment step is 210° C. to 300° C.

It is preferable that the temperature of the post-baking treatment step is 230° C. to 290° C.

It is preferable that the post-baking treatment step is performed for 30 to 120 minutes.

It is preferable that the post-baking treatment step is performed 60 to 120 minutes.

It is preferable that after the post-baking treatment step, the coating film has an optical density of 0.9/μm to 1.5/μm.

It is preferable that after the post-baking treatment step, the coating film has a roughness of 2.5 nm or less.

It is preferable that after the post-baking treatment step, the coating film has a sintering hardness of 410 N/mm² to 460 N/mm².

It is preferable that after the post-baking treatment step, the coating film has a modulus of greater than 6,200 Mpa and equal to or less than 6,700 Mpa.

It is preferable that the photosensitive composition includes a colorant.

It is preferable that the colorant includes one or more among inorganic dyes, organic dyes, inorganic pigments, and organic pigments.

It is preferable that the colorant is included in an amount of 17 wt % to 35 wt % based on the total amount of the photosensitive composition.

It is preferable that the colorant is pretreated using a dispersant; or a water-soluble inorganic salt and a wetting agent.

It is preferable that the photosensitive composition comprises a patterning resin which includes an acrylic binder resin, a cardo-based binder resin, or a combination thereof.

It is preferable that the acrylic binder resin has a weight average molecular weight of 3,000 g/mol to 150,000 g/mol.

It is preferable that the cardo-based binder resin comprises a repeating structure of Formula 1 below.

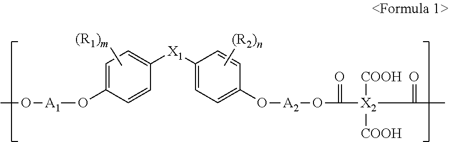

in Formula 1 above,
R₁ and R₂ are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
2) R₁ and R₂ can form a ring between neighboring groups,
3) m and n are each independently an integer of 0 to 4,
4) A₁ and A₂ are each independently Formula 2 or Formula 3 below,

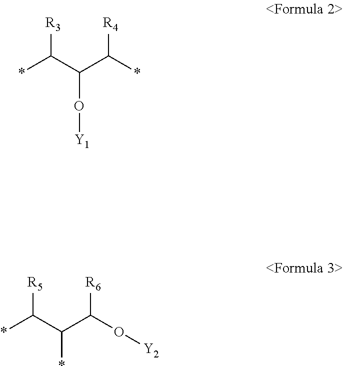

in Formula 2 and Formula 3,
4-1) * represents a connection part,
4-2) R₃ to R₆ are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
4-3) R₃ to R₆ can form a ring between neighboring groups,
4-4) Y₁ and Y₂ are each independently Formula 6 or Formula 7 below:

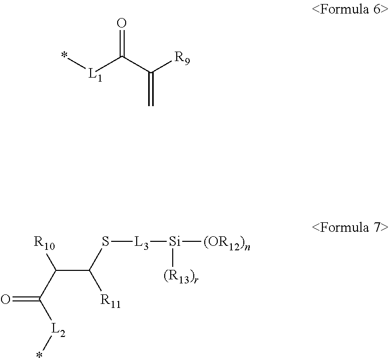

in Formula 6 and Formula 7 above,
4-4-1) * represents a binding position,
4-4-2) R₉ is hydrogen or methyl,
4-4-3) R₁₀ to R₁₃ are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
4-4-4) L₁ to L₃ are each independently a single bond, a fluorenylene group; C₂₋₃₀ alkylene; C₆₋₃₀ arylene; a C₂₋₃₀ heterocyclic ring; C₁₋₃₀ alkoxylene, C₂₋₃₀ alkyleneoxy; C₆₋₃₀ aryloxy; or C₂₋₃₀ polyethyleneoxy,
4-4-5) q and r are each independently an integer of 0 to 3; with the proviso that q+r=3,
5) the ratio of A₁ and A₂ in the polymer chain of the resin including a repeating unit represented by Formula 1 is 9:1 to 1:9,
6) X₁ is a single bond; O; CO; SO2; CR′R″; SiR′R″; Formula 4 below; or Formula 5 below,
6-1) R′ and R″ are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
6-2) R′ and R″ can form a ring between adjacent groups,

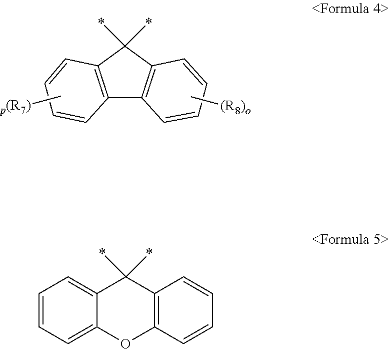

in Formula 4 and Formula 5 above,
6-3) * represents a binding position,
6-4) R₇ and R₈ are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
6-5) o and p are each independently an integer of 0 to 4,
7) X₂ is a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group, and
8) the R′, R″, X₂, L₁ to L₃, R₁ to R₈, and R₁₀ to R₁₃ can each be further substituted with one or more substituents selected from the group consisting of deuterium; a halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂-30 alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group including at least one heteroatom among O, N, S, Si, and P; a C₃₋₃₀ alicyclic group; a C₇₋₃₀ arylalkyl group; a C₈₋₃₀ arylalkenyl group; and a combination thereof, or can form a ring between the neighboring substituents.

It is preferable that the cardo-based resin has a weight average molecular weight of the 1,000 g/mol to 100,000 g/mol.

It is preferable that the cardo-based resin is included in an amount of 1 wt % to 30 wt % based on the total amount of the photosensitive composition.

It is preferable that a reactive unsaturated compound is included in an amount of 1 wt % to 40 wt % based on the total amount of the photosensitive composition.

It is preferable that a photoinitiator is included in an amount of 0.01 wt % to 10 wt % based on the total amount of the photosensitive composition.

In still another specific embodiment, it is preferable that the present disclosure provides a pixel defining layer prepared according to the above preparation method.

In still another specific embodiment, it is preferable that the present disclosure provides an organic light-emitting display device display including the pixel defining layer.

In still another specific embodiment, it is preferable that the present disclosure provides an electronic device, which includes the display device and a control unit for operating the display device.

### Effect of Invention

The present disclosure implements an organic light-emitting display having high optical density and low roughness while reducing pattern residues during pattern deposition on a film by controlling the size of inorganic pigments, thereby enabling provision of vivid colors but also increasing reliability and lifespan of the display.

In addition, pixel separation layers used in OLED displays generally have a hardness of 500 N/mm² or more and a modulus of 7,000 Mpa or more; however, they have a physical disadvantage in that they are not bendable and heavy because the provision of a polarizing plate is essential. In contrast, the pixel separation layer according to the present disclosure enables implementation of a flexible display and reduces the thickness and weight of the display. In addition, it has advantages in that visibility can be increased by blocking and absorbing external reflected light, and the hardness and modulus can be improved to the level of conventional pixel separation layers, thereby capable of implementing a display that does not generate cracks even when subjected to external impact. Ultimately, the present disclosure can realize a colored pattern with high optical density on an electrode substrate, thereby improving not only the vividness of the color but also impact resistance, reliability, and lifespan of the display.

### BRIEF DESCRIPTION OF THE DRAWING

FIG. 1 schematically illustrates the experimental results of Examples 1 to 2 and Comparative Examples 1 to 3 of the present disclosure.

FIG. 2 schematically illustrates the presence of residues in Examples 3 to 5 and Comparative Examples 4 to 7 of the present disclosure.

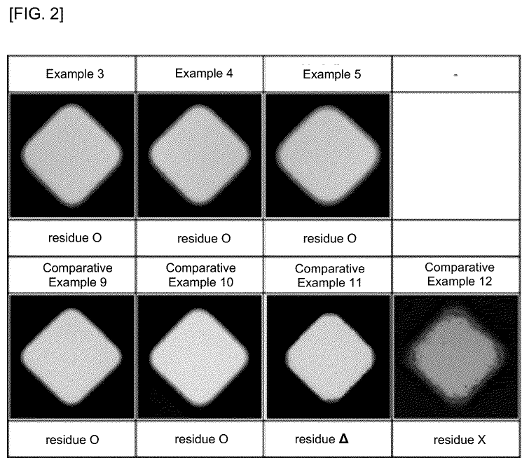

### DESCRIPTION OF EXEMPLARY EMBODIMENTS

Hereinafter, some embodiments of the present disclosure will be described in detail with reference to exemplary drawings. In adding reference numerals to components of each drawing, the same components may have the same reference numerals as far as possible even though they are indicated in different drawings.

When it is determined that a detailed description of a related known constitution or function may obscure the gist of the present disclosure in describing the present disclosure, the detailed description thereof may be omitted. When the expressions “includes”, “has”, “consisting of”, etc. mentioned in this specification are used, other parts may be added unless “only” is used. When a component is expressed in the singular form, it may include a case in which the plural form is included unless otherwise explicitly stated.

Additionally, in describing the components of the present disclosure, terms such as first, second, A, B, (a), (b), etc. may be used. Such terms are only for distinguishing the components from other components, and the essence, order, sequence, number, or etc. of the relevant components are not limited by the terms.

In the description of the positional relationship of the components, when two or more components are described as being “connected”, “linked”, or “fused”, etc., the two or more components may be directly “connected”, “linked”, or “fused”, but it should be understood that the two or more components may also be “connected”, “linked”, or “fused” by way of a further “interposition” of a different component. In particular, the different component may be included in any one or more of the two or more components that are to be “connected”, “linked”, or “fused” to each other.

Additionally, when a component such as a layer, a film, a region, a plate, or etc. is described to be “on top” or “on” of another component, it should be understood that this may not only include a case where the component is “immediately on top of” another component, but also include a case where another component is disposed therebetween. In contrast, it should be understood that when a component is described to be “immediately on top of” another part, this may mean that there is not another part disposed therebetween.

In the description of the temporal flow relationship relating to the components, the operation method, or the preparation method, for example, when the temporal precedence or flow precedence is described by way of “after”, “subsequently”, “thereafter”, “before”, etc., it may also include cases where the flow is not continuous unless terms such as “immediately” or “directly” are used.

Meanwhile, when the reference is made to numerical values or corresponding information for components, numerical values or corresponding information may be interpreted as including an error range that may occur due to various factors (e.g., process factors, internal or external shocks, noise, etc.) even if a separate explicit description is not present.

The terms used in this specification and the appended claims are as follows unless otherwise stated without departing from the spirit of the present disclosure.

The term used in this application “halo” or “halogen” includes fluorine (F), chlorine (Cl), bromine (Br), and iodine (I) unless otherwise specified.

The term used in this application “alkyl” or “alkyl group” refers to a radical of saturated aliphatic functional groups having 1 to 60 carbons linked by a single bond unless otherwise specified, and including a linear chain alkyl group, a branched chain alkyl group, a cycloalkyl (alicyclic) group, an alkyl-substituted cycloalkyl group, and a cycloalkyl-substituted alkyl group.

The term used in this application “haloalkyl group” or “halogenalkyl group” refers to an alkyl group in which a halogen is substituted unless otherwise specified.

The term used in this application “alkenyl” or “alkynyl”, unless otherwise specified, has a double bond or triple bond, respectively, includes a linear or branched chain group, and has 2 to 60 carbon atoms, but is not limited thereto.

The term used in this application “cycloalkyl” refers to alkyl which forms a ring having 3 to 60 carbon atoms unless otherwise specified, but is not limited thereto.

The term used in this application “alkoxy group” or “alkyloxy group” refers to an alkyl group to which an oxygen radical is bonded, and has 1 to 60 carbon atoms unless otherwise specified, but is not limited thereto.

The term used in this application “alkenoxyl group”, “alkenoxy group”, “alkenyloxyl group”, or “alkenyloxy group” refers to an alkenyl group to which an oxygen radical is attached, and has 2 to 60 carbon atoms unless otherwise specified, but is not limited thereto.

The term used in this application “aryl group” and “arylene group” each have 6 to 60 carbon atoms unless otherwise specified, but are not limited thereto. The aryl group or arylene group in this application includes monocyclic compounds, ring assemblies, multiple fused cyclic compounds, etc. For example, the aryl group may include a phenyl group, a monovalent functional group of biphenyl, a monovalent functional group of naphthalene, a fluorenyl group, and a substituted fluorenyl group, and the arylene group may include a fluorenylene group and a substituted fluorenylene group.

The term used in this application “ring assemblies” means that two or more ring systems (monocyclic or fused ring systems) are directly connected to each other through a single bond or double bond, and the number of direct links between such rings is one less than the total number of ring systems contained in the compound. In the ring assemblies, the same or different ring systems may be directly connected to each other through a single bond or double bond.

Since the aryl group in this application includes ring assemblies, the aryl group includes biphenyl and terphenyl in which a benzene ring, which is a single aromatic ring, is connected by a single bond. Additionally, since the aryl group also includes a compound in which an aromatic ring system fused to an aromatic single ring is connected by a single bond, it also includes, for example, a compound in which a benzene ring, which is an aromatic single ring, and fluorine, which is a fused aromatic ring system, are linked by a single bond.

The term used in this application “multiple fused ring systems” refers to a fused ring form in which at least two atoms are shared, and it includes a form in which ring systems of two or more hydrocarbons are fused, a form in which at least one heterocyclic system including at least one heteroatom is fused, etc. Such multiple fused ring systems may be an aromatic ring, a heteroaromatic ring, an aliphatic ring, or a combination of these rings. For example, in the case of an aryl group, it may be a naphthalenyl group, a phenanthrenyl group, a fluorenyl group, etc., but is not limited thereto.

The term used in this application “a spiro compound” has “a spiro union”, and the spiro union refers to a linkage in which two rings are formed by sharing only one atom. At this time, the atom shared by the two rings is called a “spiro atom”, and they are each called “monospiro-”, “dispiro-”, and “trispiro-” compounds depending on the number of spiro atoms included in a compound.

The terms used in this application “fluorenyl group”, “fluorenylene group”, and “fluorenetriyl group” refer to a monovalent, divalent, or trivalent functional group in which R, R′, R″, and R″′ are all hydrogen in the following structures, respectively, unless otherwise specified, “substituted fluorenyl group”, “substituted fluorenylene group”, or “substituted fluorenetriyl group” means that at least one of the substituents R, R′, R″, and R″′ is a substituent other than hydrogen, and cases where R and R′ are bound to each other to form a spiro compound together with carbon to which they are linked are included. In this specification, all of the fluorenyl group, the fluorenylene group, and the fluorenetriyl group may also be referred to as a fluorene group regardless of valences such as monovalent, divalent, trivalent, etc.

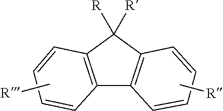

Additionally, R, R′, R″, and R″′ may each independently be an alkyl group having 1 to 20 carbon atoms, an alkenyl group having 1 to 20 carbon atoms, an aryl group having 6 to 30 carbon atoms, and a heterocyclic group having 2 to 30 carbon atoms and, for example, the aryl group may be phenyl, biphenyl, naphthalene, anthracene, or phenanthrene, and the heterocyclic group may be pyrrole, furan, thiophene, pyrazole, imidazole, triazole, pyridine, pyrimidine, pyridazine, pyrazine, triazine, indole, benzofuran, quinazoline, or quinoxaline. For example, the substituted fluorenyl group and the fluorenylene group may each be a monovalent functional group or divalent functional group of 9,9-dimethylfluorene, 9,9-diphenylfluorene, and 9,9′-spirobi[9H-fluorene].

The term used in this application “heterocyclic group” includes not only an aromatic ring such as “heteroaryl group” or “heteroarylene group”, but also a non-aromatic ring, and refers to a ring having 2 to 60 carbon atoms each including one or more heteroatoms unless otherwise specified, but is not limited thereto. The term used in this application “heteroatom” refers to N, O, S, P, or Si unless otherwise specified, and the heterocyclic group refers to a monocyclic group including a heteroatom, ring assemblies, multiple fused ring systems, spiro compounds, etc.

For example, the “heterocyclic group” may also include a compound including a heteroatom group such as SO₂, P═O, etc. such as the compound shown below, instead of carbon that forms a ring.

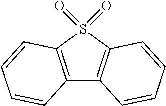 [SMILES: O=S1(=O)c2ccccc2-c2ccccc21]

The term used in this application “ring” includes monocyclic and polycyclic rings, includes heterocycles containing at least one heteroatom as well as hydrocarbon rings, and includes aromatic and non-aromatic rings.

The term used in this application “polycyclic” includes ring assemblies such as biphenyl, terphenyl, etc., multiple fused ring systems, and spiro compounds, includes non-aromatic as well as aromatic compounds, and includes heterocycles containing at least one heteroatom as well as hydrocarbon rings.

The term used in this application “alicyclic group” refers to cyclic hydrocarbons other than aromatic hydrocarbons, includes monocyclic compounds, ring assemblies, multiple fused ring systems, spiro compounds, etc., and refers to a ring having 3 to 60 carbon atoms unless otherwise specified, but is not limited thereto. For example, even when benzene, which is an aromatic ring, and cyclohexane, which is a non-aromatic ring, are fused, the alicyclic group corresponds to an aliphatic ring.

Additionally, when prefixes are named consecutively, it means that the substituents are listed in the order they are described. For example, in the case of an arylalkoxy group, it means an alkoxy group substituted with an aryl group, in the case of an alkoxycarbonyl group, it means a carbonyl group substituted with an alkoxy group, and further in the case of an arylcarbonyl alkenyl group, it means an alkenyl group substituted with an arylcarbonyl group, wherein the arylcarbonyl group is a carbonyl group substituted with an aryl group.

Additionally, unless otherwise specified, the term “substituted” in the expression “substituted or unsubstituted” as used herein refers to a substitution with one or more substituents selected from the group consisting of deuterium, a halogen, an amino group, a nitrile group, a nitro group, a C₁₋₃₀ alkyl group, a C₁₋₃₀ alkoxy group, a C₁₋₃₀ alkylamine group, a C₁₋₃₀ alkylthiophene group, a C₆₋₃₀ arylthiophene group, a C₂₋₃₀ alkenyl group, a C₂₋₃₀ alkynyl group, a C₃₋₃₀ cycloalkyl group, a C₆₋₃₀ aryl group, a C₆₋₃₀ aryl group substituted with deuterium, a C₈₋₃₀ arylalkenyl group, a silane group, a boron group, a germanium group, and a C₂₋₂₀ heterocyclic group containing one or more heteroatoms selected from the group consisting of O, N, S, Si, and P, but is not limited to these substituents.

Although the “names of functional groups” corresponding to the aryl group, arylene group, heterocyclic group, etc. exemplified as examples of each symbol and a substituent thereof in this application may be described as “names of the functional groups reflecting their valences”, they may also be described as the “names of their parent compounds”. For example, in the case of “phenanthrene”, which is a type of an aryl group, the names of the groups may also be described by classifying the valence such that the monovalent “group” is described as “phenanthryl (group)”, and the divalent group is described as “phenanthrylene (group)”, etc., but may also be described as “phenanthrene”, which is the name of its parent compound regardless of its valence.

Similarly, in the case of pyrimidine as well, it may be described regardless of its valence, or in the case of being monovalent, it may be described as pyrimidinyl (group); and in the case of being divalent, it may be described as the “name of the group” of the valence (e.g., pyrimidinylene (group)). Therefore, as used herein, when the type of a substituent is described as the name of its parent compound, it may refer to an n-valent “group” formed by detachment of a hydrogen atom linked to a carbon atom and/or heteroatom of its parent compound.

Additionally, in describing the names of the compounds or the substituents in this specification, the numbers, alphabets, etc. indicating positions may be omitted. For example, pyrido[4,3-d]pyrimidine may be described as pyridopyrimidine, benzofuro[2,3-d]pyrimidine may be described as benzofuropyrimidine, and 9,9-dimethyl-9H-fluorene may be described as dimethylfluorene. Therefore, both benzo[g]quinoxaline and benzo[f]quinoxaline may be described as benzoquinoxaline.

Additionally, unless there is an explicit description, the formulas used in this application are applied in the same manner as in the definition of substituents by the exponent definition of the formula below.

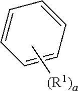

In particular, when a is an integer of 0, it means that the substituent R¹ is absent, that is, when a is 0, it means that hydrogens are linked to all carbons that form a benzene ring, and in this case, the formula or compound may be described while omitting the indication of the hydrogen linked to the carbon. Additionally, when a is an integer of 1, one substituent R¹ may be linked to any one of the carbons forming a benzene ring; when a is an integer of 2 or 3, it may be linked, for example, as shown below; even when a is an integer of 4 to 6, it may be linked to the carbon of a benzene ring in a similar manner; and when a is an integer of 2 or greater, R¹ may be the same as or different from each other.

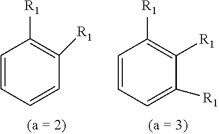

Unless otherwise specified in the present application, forming a ring means that adjacent groups bind to one another to form a single ring or multiple fused rings, and the single ring and the formed multiple fused rings may include a heterocycle containing at least one heteroatom as well as a hydrocarbon ring, and include aromatic and non-aromatic rings.

Additionally, unless otherwise specified in this specification, when indicating a condensed ring, the number in “number-condensed ring” indicates the number of rings to be condensed. For example, a form in which three rings such as anthracene, phenanthrene, benzoquinazoline, etc. are condensed with one another may be marked as a 3-condensed ring.

Meanwhile, the term used in this application “bridged bicyclic compound” refers to a compound in which two rings share 3 or more atoms to form a ring unless otherwise specified. At this time, the shared atoms may include carbon or a heteroatom.

An organic electric device in this application may refer to a component(s) between a positive electrode and a negative electrode, or may refer to an organic light-emitting diode or an organic light-emitting display device, which includes a positive electrode, a negative electrode, and a component(s) positioned therebetween.

Additionally, in some cases, the display device in this application may refer to an organic electric device, an organic light-emitting diode, and a panel including the same, or may refer to an electronic device including a panel and a circuit. In particular, for example, the electronic device may include all of a lighting device, a solar cell, a portable or mobile terminal (e.g., a smart phone, a tablet, a PDA, an electronic dictionary, a PMP, etc.), a navigation terminal, a game machine, various TV sets, various computer monitors, etc., but is not limited thereto, and may be any type of device as long as it includes the component(s).

Hereinafter, embodiments of the present disclosure will be described in detail. However, these embodiments are presented as examples, and the present disclosure is not limited thereby, and the present disclosure is only defined by the scope of the claims to be described later.

The composition containing a colorant according to one embodiment of the present disclosure may be used to prepare a pixel defining layer (PDL) with a red pattern, a green pattern, a blue pattern, or a black matrix.

A black pixel defining layer (PDL) according to one embodiment of the present disclosure may further contain an organic black pigment or black dye as an additional coloring material other than a coloring material included in the colorant described above. For example, an organic pigment may be used alone, or a mixture of an organic pigment and a coloring pigment may be used. At this time, there is an advantage in that the strength of the film (layer) or the adhesion to the substrate is not reduced even when the amount of the coloring material is relatively increased since a coloring pigment that is lack in light-shielding properties is mixed. The negative pixel define layer (PDL) according to one embodiment of the present disclosure may contain a black pigment or black dye as an additional coloring material instead of a coloring material included in the colorant described above.

Hereinafter, each component will be described in detail.

1. The process of preparing a negative pixel defining layer is as follows.

### (1) Application and Coating Step

A photosensitive composition is a low-viscosity liquid sample, and a spin coater or slit coater is used in order to coat the photosensitive resin composition to a certain thickness after applying the photosensitive resin composition onto a substrate. The spin coater has an advantage in that the flatness deviation in the area decreases although the thickness is decreased as the number of revolutions increases, and a slit coater is preferable to a spin coater in order to coat the photosensitive resin composition on a large area substrate. Due to the solvent remaining after coating, the surface may have fluidity, and there is a disadvantage in that flatness deteriorates due to this, and in order to overcome the disadvantage, the fluidity on the surface is lowered by removing a portion of the solvent using vacuum chamber dry (VCD).

### Pre-Baking Step

This is a process of removing a portion of the solvent contained in the coating film by heating the coated substrate with a hot plate or an oven at a predetermined temperature and time. When the surface or core part of the coating film is not dried, photomask contamination occurs during exposure in the next process, and when irradiated with ultraviolet light, the exposed portion does not cure well, and the pattern is not formed and removed in the development process due to non-curing.

### (3) Exposure Step

This is a process of curing a formed film by irradiating active rays (ultraviolet rays) using a photomask in which a pattern is formed when the prebaking process is finished. Types of lamps that generate active rays include LED lamps or metal (mercury) lamps, and wavelengths include g-line (436 nm), h-line (405 nm), i-line (365 nm), and deep UV (<260 nm), which can be used individually or in a mixed form.

### (4) Development Step

When irradiating active rays in the exposure step, the formed film is divided into an exposed portion and a non-exposed portion by the photo mask, and in the case of the positive type, the exposed portion is melted by a developer, and the non-exposed portion withstands the developer and the pattern remains. In the case of the negative type, the exposed portion is cured and has resistance to the developer, and the non-exposed portion is developed. The black pixel defining layer (PDL), which is prepared from a composition including a colorant of the present disclosure, is a negative type and divided into the exposed portion (curing) and the non-exposed portion (development) to form a pattern.

### (5) Post-Baking Step

This is a process to remove residual solvent and fume by applying heat to the developed substrate at a high temperature of 210° C. or higher. When the solvent and moisture are not perfectly removed in the corresponding process, the solvent and moisture remaining in the process after the post-baking affects the device, which ultimately affects the lifetime (e.g., dark spots or pixel shrinkage, etc.) of the device.

The oven temperature in the post-baking step is 230° C. to 290° C., and preferably 250° C. to 270° C.

The post-baking step is performed for 30 to 60 minutes, and preferably 60 to 120 minutes.

According to the method for preparing a pixel defining layer according to the present disclosure, it is preferable that after the post-baking treatment step, the coating film has an optical density of 0.80/μm to 2.0/μm, a sintering hardness of 350 N/mm² to 470 N/mm², and a modulus of 5,200 Mpa to 6,800 Mpa.

It is preferable that after the post-baking treatment step, the coating film has a sintering hardness of 410 N/mm² to 460 N/mm².

It is preferable that after the post-baking treatment step, the coating film has a modulus of greater than 6,200 Mpa and equal to or less than 6,700 Mpa.

It is preferable that after the post-baking treatment step, the coating film has an optical density of 0.90/μm to 1.50/μm.

2. A composition forming a negative pixel defining layer containing a colorant is as follows.

### (1) Patterning Resin

The patterning resin according to one embodiment of the present disclosure may include a cardo-based binder resin.

The acrylic binder resin is a copolymer of a first ethylenically unsaturated monomer and a second ethylenically unsaturated monomer copolymerizable therewith, and is a resin including one or more acrylic repeating units.

The first ethylenically unsaturated monomer is an ethylenically unsaturated monomer containing one or more carboxyl groups, and specific examples thereof may include acrylic acid, methacrylic acid, maleic acid, itaconic acid, fumaric acid, or combinations thereof. The first ethylenically unsaturated monomer may be contained in an amount of 5 wt % to 50 wt %, for example, 10 wt % to 40 wt % based on the total amount of the acrylic binder resin.

The second ethylenically unsaturated monomer may include aromatic vinyl compounds such as styrene, α-methylstyrene, vinyltoluene, vinylbenzyl methyl ether, etc.; unsaturated carboxylic acid ester compounds such as methyl (meth)acrylate, ethyl (meth)acrylate, butyl (meth)acrylate, 2-hydroxyethyl (meth)acrylate, 2-hydroxy butyl (meth)acrylate, benzyl (meth)acrylate, cyclohexyl (meth)acrylate, phenyl (meth)acrylate, etc.; unsaturated carboxylic acid amino alkyl ester compounds such as 2-aminoethyl (meth)acrylate, 2-dimethylaminoethyl (meth)acrylate, etc.; carboxylic acid vinyl ester compounds such as vinyl acetate, etc.; unsaturated carboxylic acid glycidyl ester compounds such as glycidyl (meth)acrylate, etc.; vinyl cyanide compounds such as (meth)acrylonitrile, etc.; and unsaturated amide compounds such as (meth)acrylamide, etc., and these may be used alone or in mixtures of two or more.

Specific examples of the acrylic binder resin may include a (meth)acrylic acid/benzyl methacrylate copolymer, a (meth)acrylic acid/benzyl methacrylate/styrene copolymer, a (meth)acrylic acid/benzyl methacrylate/2-hydroxyethyl methacrylate copolymer, a (meth)acrylic acid/benzyl methacrylate/styrene/2-hydroxyethyl methacrylate copolymer, etc., but are not limited thereto. These may be used alone or in a mixture of two or more. The acrylic binder resin may have a weight average molecular weight of 3,000 g/mol to 150,000 g/mol, for example, 5,000 g/mol to 50,000 g/mol, for example, 20,000 g/mol to 30,000 g/mol.

The cardo-based resin includes a repeating structure as shown in Formula 1 below.

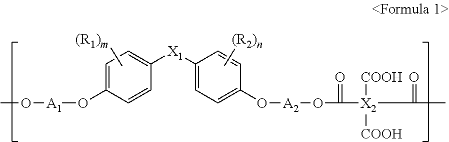

in Formula 1 above,
1) R₁ and R₂ are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
2) R₁ and R₂ can form a ring between neighboring groups,
3) m and n are each independently an integer of 0 to 4,
4) A₁ and A₂ are each independently Formula 2 or Formula 3 below,

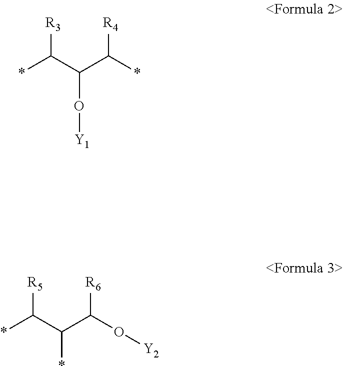

in Formula 2 and Formula 3,
4-1) * represents a connection part,
4-2) R₃ to R₆ are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
4-3) R₃ to R₆ can form a ring between neighboring groups,
4-4) Y₁ and Y₂ are each independently Formula 6 or Formula 7 below:

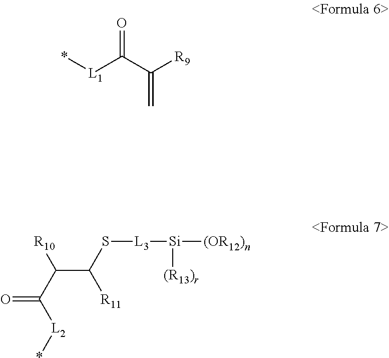

in Formula 6 and Formula 7 above,
4-4-1) * represents a binding position,
4-4-2) R₉ is hydrogen or methyl,
4-4-3) R₁₀ to R₁₃ are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
4-4-4) L₁ to L₃ are each independently a single bond, a fluorenylene group; C₂₋₃₀ alkylene; C₆₋₃₀ arylene; a C₂₋₃₀ heterocyclic ring; C₁₋₃₀ alkoxylene, C₂₋₃₀ alkyleneoxy; C₆₋₃₀ aryloxy; or C₂₋₃₀ polyethyleneoxy,
4-4-5) q and r are each independently an integer of 0 to 3; with the proviso that q+r=3,
5) the ratio of A₁ and A₂ in the polymer chain of the resin including a repeating unit represented by Formula 1 is 9:1 to 1:9,
6) X₁ is a single bond; O; CO; SO2; CR′R″; SiR′R″; Formula 4 below; or Formula 5 below,
6-1) R′ and R″ are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
6-2) R′ and R″ can form a ring between adjacent groups,

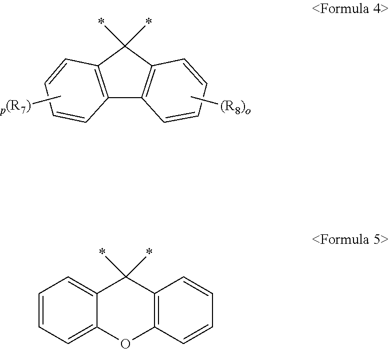

in Formula 4 and Formula 5 above,
6-3) * represents a binding position,
6-4) R₇ and R₈ are each independently hydrogen; deuterium; a halogen; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
6-5) o and p are each independently an integer of 0 to 4,
7) X₂ is a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group, and
8) the R′, R″, X₂, L₁ to L₃, R₁ to R₈, and R₁₀ to R₁₃ can each be further substituted with one or more substituents selected from the group consisting of deuterium; a halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂-30 alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group including at least one heteroatom among O, N, S, Si, and P; a C₃₋₃₀ alicyclic group; a C₇₋₃₀ arylalkyl group; a C₈₋₃₀ arylalkenyl group; and a combination thereof, or can form a ring between the neighboring substituents.

When R′, R″, X₂, L₁ to L₃, R₁ to R₈, and R₁₀ to R₁₃ are an aryl group, they may preferably be a C₆₋₃₀ aryl group, and more preferably a C₆₋₁₈ aryl group, for example, phenyl, biphenyl, naphthyl, terphenyl, etc.

When R′, R″, X₂, L₁ to L₃, R₁ to R₈, and R₁₀ to R₁₃ are a heterocyclic group, they may preferably be a C₂₋₃₀ heterocyclic group, and more preferably a C₂₋₁₈ heterocyclic group, for example, dibenzofuran, dibenzothiophene, naphthobenzothiophene, naphthobenzofuran, etc.

When R′, R″, R₁ to R₈, and R₁₀ to R₁₃ are a fluorenyl group, they may preferably be 9,9-dimethyl-9H-fluorene, 9,9-diphenyl-9H-fluorenyl group, 9,9′-spirobifluorene, etc.

When L₁ to L₃ are an arylene group, they may preferably be a C₆₋₃₀ arylene group, and more preferably a C₆₋₁₈ arylene group, for example, phenyl, biphenyl, naphthyl, terphenyl, etc.

When R′, R″, X₂, R₁ to R₈, and R₁₀ to R₁₃ are an alkyl group, they may preferably be a C₁₋₁₀ alkyl group, for example, methyl, t-butyl, etc.

When R′, R″, X₂, R₁ to R₈, and R₁₀ to R₁₃ are an alkoxyl group, they may preferably be a C₁-C₂₀ alkoxyl group, and more preferably a C₁-C₁₀ alkoxyl group, for example, methoxy, t-butoxy, etc.

Rings formed by binding between neighboring groups of R′, R″, X₂, L₁ to L₃, R₁ to R₈, and R₁₀ to R₁₃ may be a C₆₋₃₀ aromatic ring; a fluorenyl group; a C₂₋₆₀ heterocyclic group containing at least one heteroatom of O, N, S, Si, and P; or a C₃-C₆₀ alicyclic group, and for example, when the neighboring groups bind with each other to form an aromatic ring, preferably, a C₆₋₂₀ aromatic ring, and more preferably a C₆₋₁₄ aromatic ring, for example, benzene, naphthalene, phenanthrene, etc. may be formed.

The cardo-based resin may be prepared by mixing two or more of, for example, fluorene-containing compounds such as 9,9-bis(4-oxiranylmethoxyphenyl)fluorene, etc.; anhydride compounds such as a benzene tetracarboxylic acid dianhydride, a naphthalene tetracarboxylic acid dianhydride, a biphenyltetracarboxylic acid dianhydride, a benzophenonetetracarboxylic acid dianhydride, a pyromellitic acid dianhydride, a cyclobutanetetracarboxylic acid dianhydride, a perylenetetracarboxylic acid dianhydride, a tetrahydrofurantetracarboxylic acid dianhydride, a tetrahydrophthalic acid anhydride, etc.; glycol compounds such as ethylene glycol, propylene glycol, polyethylene glycol, etc.; alcohol compounds such as methanol, ethanol, propanol, n-butanol, cyclohexanol, benzyl alcohol, etc.; solvent compounds such as propylene glycol methylethyl acetate, N-methylpyrrolidone, etc.; phosphorus compounds such as triphenylphosphine, etc.; and amine or ammonium salt compounds such as tetramethylammonium chloride, tetraethylammonium bromide, benzyldiethylamine, triethylamine, tributylamine, benzyltriethylammonium chloride, etc.

The cardo-based resin may have a weight average molecular weight of 1,000 g/mol to 100,000 g/mol, preferably 1,000 g/mol to 50,000 g/mol, and more preferably 1,000 g/mol to 30,000 g/mol. When the weight average molecular weight of the resin is within the above-described range, the pattern formation is well performed without residue during the preparation of a light-shielding layer, there is no loss of film thickness during development, and a good pattern may be obtained. The resin may be contained in an amount of 1 wt % to 30 wt %, and more preferably 3 wt % to 20 wt % based on the total amount of the photosensitive resin composition. When the resin is contained within the above-described range, excellent sensitivity, developing properties, and adhesiveness (adhesion) can be obtained.

### (2) Reactive Unsaturated Compound

A reactive unsaturated compound that is absolutely necessary for negative patterns may form a pattern having excellent heat resistance, light resistance, and chemical resistance by causing sufficient polymerization during exposure in the pattern forming process by having an ethylenically unsaturated double bond.

Specific examples of the reactive unsaturated compound may include ethylene glycol diacrylate, ethylene glycol dimethacrylate, diethylene glycol diacrylate, triethylene glycol diacrylate, triethylene glycol dimethacrylate, 1,6-hexanediol diacrylate, 1,6-hexanediol dimethacrylate, pentaerythritol triacrylate, dipentaerythritol pentaacrylate, dipentaerythritol hexaacrylate, bisphenol A epoxy acrylate, ethylene glycol monomethyl ether acrylate, trimethylolpropane triacrylate, tripentaerythritol octaacrylate, etc.

Examples of commercially available products of the reactive unsaturated compound are as follows.

Examples of a bifunctional ester of (meth)acrylic acid may include Aronix M-210, M-240, M-6200, etc. of Toa Kosei Kagaku Kogyo Co., Ltd.; KAYARAD HDDA, HX-220, R-604, etc. of Nippon Kayaku Co., Ltd.; and V-260, V-312, V-335 HP, etc. of Osaka Yuki Kagaku Kogyo Co., Ltd.

Examples of a trifunctional ester of (meth)acrylic acid may include Aronix M-309, M-400, M-405, M-450, M-7100, M-8030, M-8060, etc. of Toa Kosei Kagaku Kogyo Co., Ltd.; KAYARAD TMPTA, DPCA-20, DPCA-60, DPCA-120, etc. of Nippon Kayaku Co., Ltd.; and V-295, V-300, V-360, etc. of Osaka Yuki Kagaku Kogyo Co., Ltd.

The above products may be used alone or used together in combinations of two or more.

The reactive unsaturated compound may be used after being treated with an acid anhydride so as to impart more excellent developing properties. The reactive unsaturated compound may be contained in an amount of 1 wt % to 40 wt %, for example, 1 wt % to 20 wt % based on the total amount of the photosensitive resin composition. When the reactive unsaturated compound is contained within the above-described range, sufficient curing occurs during exposure in the pattern forming process so that reliability is excellent, heat resistance, light resistance, and chemical resistance of the pattern are excellent, and resolution and adhesion are also excellent.

### (3) Photoinitiator

A photoradical initiator should be used in order to implement a negative pattern with photolithography. The photoinitiator is a photoinitiator which has a molar absorption coefficient of 10,000 L/mol-cm or more in the region of 330 nm to 380 nm and of which a 5 wt % loss occurs at 200° C. or lower. In particular, the molar extinction coefficient may be calculated by Beer-Lambert Law. Additionally, the weight loss was measured while raising the temperature to 300° C. at a rate of 5° C. per minute under a nitrogen atmosphere using TGA.

The photoinitiator is an initiator generally used in photosensitive resin compositions, and examples thereof may include an acetophenone-based compound, a benzophenone-based compound, a thioxanthone-based compound, a benzoin-based compound, a triazine-based compound, etc.

Examples of the acetophenone-based compound may include 2,2′-diethoxy acetophenone, 2,2′-dibutoxy acetophenone, 2-hydroxy-2-methylpropiophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, etc.

Examples of the benzophenone-based compound may include benzophenone, benzoyl benzoate, methyl benzoyl benzoate, 4-phenyl benzophenone, hydroxy benzophenone, acrylated benzophenone, 4,4′-bis(dimethylamino)benzophenone, 4,4′-bis(diethylamino)benzophenone, 4,4′-dimethylaminobenzophenone, 4,4′-dichlorobenzophenone, 3,3′-dimethyl-2-methoxybenzophenone, etc.

Examples of the thioxanthone-based compound may include thioxanthone, 2-chlorothioxanthone, 2-methylthioxanthone, isopropyl thioxanthone, 2,4-diethyl thioxanthone, 2,4-diisopropyl thioxanthone, 2-chlorothioxanthone, etc.

Examples of the benzoin-based compound may include benzoin, benzoin methyl ether, benzoin ethyl ether, benzoin isopropyl ether, benzoin isobutyl ether, benzyldimethyl ketal, etc.

Examples of the triazine-based compound may include 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl 4,6-bis(trichloromethyl)-s-triazine, bis(trichloromethyl)-6-styryl-s-triazine, 2-(naphtho-1-yl)-4,6-bis(trichloromethyl)-s-triazine, 2-(4-methoxy-naphtho-1-yl)-4,6-bis(trichloromethyl)-s-triazine, 2-4-trichloromethyl(piperonyl)-6-triazine, 2-4-trichloromethyl(4′-methoxystyryl)-6-triazine, etc.

The photoinitiator may include carbazole-based compounds, diketone-based compounds, sulfonium borate-based compounds, diazo-based compounds, imidazole-based compounds, non-imidazole-based compounds, etc., in addition to the above compounds.

The photoinitiator may include a peroxide-based compound, an azobis-based compound, etc. as radical polymerization initiators.

Examples of the peroxide-based compound may include ketone peroxides such as methyl ethyl ketone peroxide, methyl isobutyl ketone peroxide, cyclohexanone peroxide, methylcyclohexanone peroxide, acetylacetone peroxide, etc.; diacyl peroxides such as isobutyryl peroxide, 2,4-dichlorobenzoyl peroxide, o-methylbenzoyl peroxide, bis-3,5,5-trimethylhexanoyl peroxide, etc.; hydroperoxides such as 2,4,4,-trimethylpentyl-2-hydroperoxide, diisopropylbenzene hydroperoxide, cumene hydroperoxide, t-butyl hydroperoxide, etc.; dialkyl peroxides such as dicumyl peroxide, 2,5-dimethyl-2,5-di(t-butylperoxy)hexane, 1,3-bis(t-butyloxyisopropyl)benzene, t-butylperoxyvalerate n-butyl ester, etc.; alkyl peresters such as 2,4,4-trimethylpentyl peroxyphenoxyacetate, α-cumyl peroxyneodecanoate, t-butyl peroxybenzoate, di-t-butyl peroxytrimethyl adipate, etc.; and percarbonates such as di-3-methoxybutyl peroxydicarbonate, di-2-ethylhexyl peroxydicarbonate, bis-4-t-butylcyclohexyl peroxydicarbonate, diisopropyl peroxydicarbonate, acetylcyclohexylsulfonyl peroxide, t-butyl peroxyaryl carbonate, etc.

Examples of the azobis-based compound may include 1,1′-azobiscyclohexan-1-carbonitrile, 2,2′-azobis(2,4-dimethylvaleronitrile), 2,2,-azobis(methylisobutyrate), 2,2′-azobis(4-methoxy-2,4-dimethylvaleronitrile), α,α′-azobis(isobutylnitrile), 4,4′-azobis(4-cyanovaleric acid), etc.

The photoinitiator may be used together with a photosensitizer that causes a chemical reaction by absorbing light and thus becoming an excited state and then transferring the energy of light. Examples of the photosensitizer may include tetraethylene glycol bis-3-mercaptopropionate, pentaerythritol tetrakis-3-mercaptopropionate, dipentaerythritol tetrakis-3-mercaptopropionate, etc.

The photoinitiator may be contained in an amount of 0.01 wt % to 10 wt %, for example, 0.1 wt % to 5 wt % based on the total amount of the photosensitive resin composition. When the photoinitiator is contained within the above-described range, curing occurs sufficiently during exposure in the pattern forming process so that excellent reliability may be obtained, heat resistance, light resistance, and chemical resistance of the pattern are excellent, resolution and adhesion are also excellent, and a decrease in transmittance due to an unreacted initiator may be prevented.

### (4) Colorant

All of organic and inorganic pigments and dyes can be used as the colorant.

The colorant may include a red pigment, a green pigment, a blue pigment, a yellow pigment, a black pigment, etc.

Examples of the red pigment may include C.I. Red Pigment 254, C.I. Red Pigment 255, C.I. Red Pigment 264, C.I. Red Pigment 270, C.I. Red Pigment 272, C.I. Red Pigment 177, C.I. Red Pigment 89, etc.

Examples of the green pigment may include halogen-substituted copper phthalocyanine pigments such as C.I. Green Pigment 36, C.I. Green Pigment 7, etc.

Examples of the blue pigment may include copper phthalocyanine pigments such as C.I. Blue Pigment 15:6, C.I. Blue Pigment 15, C.I. Blue Pigment 15:1, C.I. Blue Pigment 15:2, C.I. Blue Pigment 15:3, C.I. Blue Pigment 15:4, C.I. Blue Pigment 15:5, C.I. Blue Pigment 16, etc.

Examples of the yellow pigment may include isoindoline-based pigments such as C.I. Yellow Pigment 139, etc., quinophthalone-based pigments such as C.I. Yellow Pigment 138, etc., and nickel complex pigments such as C.I. Yellow Pigment 150, etc.

Examples of the black pigment may include, for example, lactam black, aniline black, perylene black, titanium black, carbon black, etc.

Additionally, the colorant in the photosensitive resin composition according to the embodiment may include pigments, dyes, or combinations thereof. For example, the dyes may include phthalocyanine-based compounds.

The pigments and dyes may be used alone or in a mixture of two or more, but are not limited to examples thereof.

Among them, the black pigment may be used in order to effectively perform light-shielding of the light-shielding layer. When the black pigment is used, it may be used together with color correcting agents such as anthraquinone-based pigments, perylene-based pigments, phthalocyanine-based pigments, azo-based pigments, etc.

In order to disperse the pigment in the photosensitive resin composition, a dispersant may be used together. Specifically, the pigment may be surface-treated with a dispersant in advance and used, or a dispersant may be added together with the pigment and used during preparation of the photosensitive resin composition.

The dispersant may include a nonionic dispersant, an anionic dispersant, a cationic dispersant, etc. Specific examples of the dispersant may include polyalkylene glycol and an ester thereof, polyoxyalkylene, a polyhydric alcohol ester alkylene oxide adduct, an alcohol alkylene oxide adduct, a sulfonic acid ester, a sulfonic acid salt, a carboxylic acid ester, a carboxylic acid salt, an alkylamide alkylene oxide adduct, alkyl amine, etc., and these may be used alone or in mixtures of two or more.

Examples of commercially available products of the dispersant include DISPERBYK-101, DISPERBYK-130, DISPERBYK-140, DISPERBYK-160, DISPERBYK-161, DISPERBYK-162, DISPERBYK-163, DISPERBYK-164, DISPERBYK-165, DISPERBYK-166, DISPERBYK-170, DISPERBYK-171, DISPERBYK-182, DISPERBYK-2000, DISPERBYK-2001, etc. from BYK; EFKA-47, EFKA-47EA, EFKA-48, EFKA-49, EFKA-100, EFKA-400, EFKA-450, etc. from EFKA Chemical; Solsperse 5000, Solsperse 12000, Solsperse 13240, Solsperse 13940, Solsperse 17000, Solsperse 20000, Solsperse 24000GR, Solsperse 27000, Solsperse 28000, etc. from Zeneka; or PB711, PB821, etc. from Ajinomoto.

The dispersant may be contained in an amount of 0.1 wt % to 15 wt % based on the total amount of the photosensitive resin composition. When the dispersant is contained within the above-described range, stability, developing properties, and patternability of the composition are excellent when preparing the light-shielding layer due to excellent dispersibility of the composition.

The pigment may be pretreated using a water-soluble inorganic salt and a wetting agent and used. When the pigment is pretreated and used as described above, the average particle diameter of the pigment may be refined.

The pretreatment may be performed through a step of kneading the pigment together with a water-soluble inorganic salt and a wetting agent, and a step of filtering and washing the pigment obtained in the kneading step.

The kneading may be performed at a temperature of 40° C. to 100° C., and the filtration and washing may be performed by washing the inorganic salt using water, etc. and then performing filtration.

Examples of the water-soluble inorganic salt may include sodium chloride, potassium chloride, etc., but are not limited thereto.

The wetting agent serves as a medium through which the pigment and the water-soluble inorganic salt may be uniformly mixed to pulverize the pigment easily, and examples of the wetting agent may include alkylene glycol monoalkyl ethers such as ethylene glycol monoethyl ether, propylene glycol monomethyl ether, diethylene glycol monomethyl ether, etc.; and alcohols such as ethanol, isopropanol, butanol, hexanol, cyclohexanol, ethylene glycol, diethylene glycol, polyethylene glycol, glycerin polyethylene glycol, etc., and these may be used alone or in mixtures of two or more.

The pigment that has gone through the kneading step may have an average particle diameter of 120 nm or less. When the average particle diameter of the pigment is within the above-described range, a fine pattern may be effectively formed while having excellent heat resistance and light resistance.

The pigment may be contained in an amount of 1 wt % to 40 wt %, and more specifically 17 wt % to 35 wt % based on the total amount of the photosensitive resin composition. When the pigment is contained within the above-described range, the color reproduction rate is excellent, and the curability and adhesion of the pattern are excellent.

### (5) Solvent

The solvent may include materials which are compatible with the cardo-based resin, the reactive unsaturated compound, the pigment, the cardo-based compound, and the initiator, but do not react therewith.

Examples of the solvent include alcohols such as methanol, ethanol, etc.; ethers such as dichloroethyl ether, n-butyl ether, diisoamyl ether, methylphenyl ether, tetrahydrofuran, etc.; glycol ethers such as ethylene glycol monomethyl ether, ethylene glycol monoethyl ether, etc.; cellosolve acetates such as methyl cellosolve acetate, ethyl cellosolve acetate, diethyl cellosolve acetate, etc.; carbitols such as methylethyl carbitol, diethyl carbitol, diethylene glycol monomethyl ether, diethylene glycol monoethyl ether, diethylene glycol dimethyl ether, diethylene glycol methyl ethyl ether, diethylene glycol diethyl ether, etc.; propylene glycol alkyl ether acetates such as propylene glycol methyl ether acetate, propylene glycol propyl ether acetate, etc.; aromatic hydrocarbons such as toluene, xylene, etc.; ketones such as methyl ethyl ketone, cyclohexanone, 4-hydroxy-4-methyl-2-pentanone, methyl-n-propyl ketone, methyl-n-butyl ketone, methyl-n-amyl ketone, 2-heptanone, etc.; saturated aliphatic monocarboxylic acid alkyl esters such as ethyl acetate, n-butyl acetate, isobutyl acetate, etc.; lactic acid esters such as methyl lactate, ethyl lactate, etc.; oxyacetic acid alkyl esters such as methyl oxyacetate, ethyl oxyacetate, butyl oxyacetate, etc.; alkoxy acetate alkyl esters such as methoxy methyl acetate, methoxy ethyl acetate, methoxy butyl acetate, ethoxy methyl acetate, ethoxy ethyl acetate, etc.; 3-oxypropionic acid alkyl esters such as 3-oxy methyl propionate, 3-oxy ethyl propionate, etc.; 3-alkoxy propionic acid alkyl esters such as 3-methoxy methyl propionate, 3-methoxy ethyl propionate, 3-ethoxy ethyl propionate, 3-ethoxy methyl propionate, etc.; 2-oxypropionic acid alkyl esters such as methyl 2-oxypropionate, ethyl 2-oxypropionate, propyl 2-oxypropionate, etc.; 2-alkoxy propionic acid alkyl esters such as 2-methoxy methyl propionate, 2-methoxy ethyl propionate, 2-ethoxy ethyl propionate, 2-ethoxy methyl propionate, etc.; monooxy monocarboxylic acid alkyl esters of 2-oxy-2-methyl propionic acid esters such as 2-oxy-2-methyl methyl propionate, 2-oxy-2-methyl ethyl propionate, etc., and 2-alkoxy-2-methyl propionic acid alkyls such as 2-methoxy-2-methyl methyl propionate, 2-ethoxy-2-methyl ethyl propionate, etc.; esters such as 2-hydroxyethyl propionate, 2-hydroxy-2-methyl ethyl propionate, ethyl hydroxyacetate, 2-hydroxy-3-methyl methyl butanoate, etc.; and ketonic acid esters such as ethyl pyruvate, etc.

Further, high-boiling point solvents such as N-methylformamide, N,N-dimethylformamide, N-methylformanilide, N-methylacetamide, N,N-dimethylacetamide, N-methylpyrrolidone, dimethyl sulfoxide, benzyl ethyl ether, dihexyl ether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, and phenyl cellosolve acetate may also be used.

Considering compatibility and reactivity, glycol ethers such as ethylene glycol monoethyl ether, etc.; ethylene glycol alkyl ether acetates such as ethyl cellosolve acetate, etc.; esters such as ethyl 2-hydroxypropionate, etc.; carbitols such as diethylene glycol monomethyl ether, etc.); and propylene glycol alkyl ether acetates such as propylene glycol methyl ether acetate, propylene glycol propyl ether acetate, etc. among the above solvents may be used.

The solvent may be contained as a balance amount based on the total amount of the photosensitive resin composition, and specifically in an amount of 40 wt % to 90 wt %. When the solvent is contained within the above-described range, the processability when preparing the pattern layer is excellent as the photosensitive resin composition has an appropriate viscosity.

### (6) Other Additives

In order to prevent stains or spots during application, to improve leveling performance, and to prevent the generation of residues due to nondevelopment, the photosensitive composition may further include additives including: malonic acid; 3-amino-1,2-propanediol; a silane-based coupling agent containing a vinyl group or (meth)acryloxy group; a leveling agent; a fluorine-based surfactant; a silicone-based surfactant; a radical polymerization initiator; etc.

For example, the photosensitive resin composition may further include a silane-based coupling agent having a reactive substituent such as a vinyl group, a carboxyl group, a methacryloxy group, an isocyanate group, an epoxy group, etc. in order to improve adhesion to a substrate, etc.

Examples of the silane-based coupling agent may include trimethoxysilyl benzoic acid, 7-methacryloxypropyl trimethoxysilane, vinyl triacetoxysilane, vinyl trimethoxysilane, 7-isocyanate propyl triethoxysilane, 7-glycidoxy propyl trimethoxy silane, 3-epoxy cyclohexyl ethyl trimethoxy silane, etc., and these may be used alone or in mixtures of two or more.

The silane-based coupling agent may be contained in an amount of 0.01 to 10 parts by weight based on 100 parts by weight of the photosensitive resin composition. When the silane-based coupling agent is contained within the above-described range, adhesion, storability, etc. are excellent.

Additionally, the photosensitive resin composition may further include a surfactant, for example, a fluorine-based surfactant or a silicone-based surfactant for the effects of improving coating properties and preventing creation of defects, if necessary.

The fluorine-based surfactant may include fluorine-based surfactants commercially available under the names of: BM-1000®, BM-1100®, etc. from BM Chemie; Mega pack F 142D®, Mega pack F 172®, Mega pack F 173®, Mega pack F 183®, etc. from Dainippon Ink Kagaku Kogyo; Fluorad FC-135®, Fluorad FC-170C®, Fluorad FC-4130®, Fluorad FC-431® etc. from Sumitomo 3M Saffron S-112®, Saffron S-113®, Samron S-131®, Samron S-141®, Saffron S-145®, etc, from Asabi Grass; and SH-28PA®, SH-190®, SH-193®, SZ-6032®, SF-8428®, etc. from Toray Silicone.

The surfactant may be used in an amount of 0.001 to 5 parts by weight based on 100 parts by weight of the photosensitive resin composition. When the surfactant is contained within the above-described range, coating uniformity may be secured, stains may not occur, and wetting to the glass substrate is excellent. Additionally, a certain amount of other additives such as antioxidants and stabilizers may be added to the photosensitive resin composition within a range that does not impair physical properties.

Another embodiment may perform a patterning on a pixel separation part of an organic light-emitting device electrode using the photosensitive resin composition described above.

Hereinafter, Synthetic Examples and Examples according to the present disclosure are specifically described, but these Synthetic Examples and Examples of the present disclosure are not limited thereto.

### (Preparation of Black Photosensitive Composition)

### Synthesis Example 1: (Preparation of 9,9-bis[4-(glycidyloxy)phenyl]fluorene of Formula 8)

20 g of 9,9′-bisphenol fluorene (Sigma Aldrich), 8.67 g of glycidyl chloride (Sigma Aldrich), and 30 g of anhydrous potassium carbonate were added into a 300 mL 3-neck round-bottom flask having a distillation tube installed thereon together with 100 mL of dimethylformamide, and the temperature was raised to 80° C. and reacted for 4 hours. Then, the temperature was lowered to 25° C. to filter the reaction solution, and the filtrate was added dropwise to 1,000 mL of water while stirring, and the precipitated powder was filtered, washed with water, and dried under reduced pressure at 40° C. to thereby obtain 25 g of 9,9-bis[4-(glycidyloxy)phenyl]fluorene of Formula 8 below. As a result of purity analysis of the obtained powder by HPLC, a purity of 98% was shown.

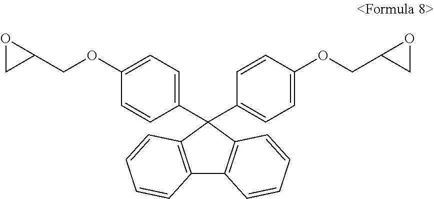 [SMILES: c1ccc2c(c1)-c1ccccc1C2(c1ccc(OCC2CO2)cc1)c1ccc(OCC2CO2)cc1]

### Synthesis Example 2: Preparation of Cardo-Based Binder Resin

25 g (54 mmol) of Compound 1 obtained in Synthesis Example 1, 8 g of acrylic acid (Daejung Chemicals & Metals Co., Ltd.), 0.2 g of benzyltriethylammonium chloride (Daejung Chemicals & Metals Co., Ltd.), and 0.2 g of hydroquinone (Daejung Chemicals & Metals Co., Ltd.) together with 52 g of propylene glycol methyl ether acetate (Sigma Aldrich) were added into a 300 mL 3-neck round-bottom flask having a distillation tube installed thereon, and the mixture was stirred at 110° C. for 6 hours. After completion of the reaction, 8 g of biphenyltetracarboxylic dianhydride (Mitsubishi Gas) and 1.8 g of tetrahydrophthalic acid (Sigma Aldrich) were added thereto, and the mixture was stirred again at 110° C. for 6 hours. After completion of the reaction, the reaction solution was recovered and analyzed, and as a result, it was found that a cardo-based binder resin having a molecular weight of 4,580 and a solid content of 45% was obtained.

### Preparation Example 1: Preparation of Black Pigment Dispersion

A dispersion was obtained by dispersing 15 g of Irgaphor Black S 100 CF (black pigment/BASF), 8.5 g of Disperbyk 163 (BYK), and 6.5 g of SR-3613 (SMS) together with 70 g of propylene glycol methyl ether acetate for 10 hours using a paint shaker (Asada) of 100 g of zirconia beads with a diameter of 0.5 mm (Toray). The average particle size of the dispersion was confirmed to be 97 nm using a particle size analyzer (SZ-100Z, HORIBA).

### Preparation Example 2: Preparation of Black Pigment Dispersion

A dispersion was obtained by dispersing 15 g of Irgaphor Black S 100 CF (black pigment/BASF), 8.5 g of Disperbyk 163 (BYK), and 6.5 g of SR-3613 (SMS) together with 70 g of propylene glycol methyl ether acetate for 12 hours using a paint shaker (Asada) of 100 g of zirconia beads with a diameter of 0.5 mm (Toray). The average particle size of the dispersion was confirmed to be 75.3 nm using a particle size analyzer (SZ-100Z, HORIBA).

### Preparation Example 3: Preparation of Black Pigment Dispersion

A dispersion was obtained by dispersing 15 g of Irgaphor Black S 100 CF (black pigment/BASF), 8.5 g of Disperbyk 163 (BYK), and 6.5 g of SR-3613 (SMS) together with 70 g of propylene glycol methyl ether acetate for 8 hours using a paint shaker (Asada) of 100 g of zirconia beads with a diameter of 0.5 mm (Toray). The average particle size of the dispersion was confirmed to be 133.9 nm using a particle size analyzer (SZ-100Z, HORIBA).

### Preparation Example 4: Preparation of Black Pigment Dispersion

A dispersion was obtained by dispersing 15 g of Irgaphor Black S 100 CF (black pigment/BASF), 8.5 g of Disperbyk 163 (BYK), and 6.5 g of SR-3613 (SMS) together with 70 g of propylene glycol methyl ether acetate for 7 hours using a paint shaker (Asada) of 100 g of zirconia beads with a diameter of 0.5 mm (Toray). The average particle size of the dispersion was confirmed to be 156.8 nm using a particle size analyzer (SZ-100Z, HORIBA).

### Preparation Example 5: Preparation of Black Pigment Dispersion

A dispersion was obtained by dispersing 15 g of Irgaphor Black S 100 CF (black pigment/BASF), 8.5 g of Disperbyk 163 (BYK), and 6.5 g of SR-3613 (SMS) together with 70 g of propylene glycol methyl ether acetate for 6 hours using a paint shaker (Asada) of 100 g of zirconia beads with a diameter of0.5 mm (Toray). The average particle size ofthe dispersion was confirmed to be 168.6 nm using a particle size analyzer (SZ-100Z, HORIBA).

Photosensitive composition solutions were prepared with the compositions as shown in Table 1 below.

Specifically, after dissolving an initiator in a solvent, the resultant was stirred at room temperature, and then a binder resin and a polymerizable compound were added thereto and the mixture was stirred at room temperature. Then, a colorant and other additives were added to the obtained reactants, and the mixture was stirred at room temperature. Subsequently, the reaction product was filtered three times to remove impurities, thereby preparing each photosensitive resin composition.

TABLE 1

| | Comparative | Comparative | Comparative | | |
|---|---|---|---|---|---|
| | Example 1 | Example 2 | Example 3 | Example 1 | Example 2 |
| Black Pigment Dispersion | | | | 23 | |
| (Preparation Example 1) | | | | | |
| Black Pigment Dispersion | | | | | 23 |
| (Preparation Example 2) | | | | | |
| Black Pigment Dispersion | 23 | | | | |
| (Preparation Example 3) | | | | | |
| Black Pigment Dispersion | | 23 | | | |
| (Preparation Example 4) | | | | | |
| Black Pigment Dispersion | | | 23 | | |
| (Preparation Example 5) | | | | | |
| Cardo Binder | 15 | 15 | 15 | 15 | 15 |
| (Synthesis Example 2) | | | | | |
| Miraemer M600 (Miwon | 12.5 | 12.5 | 12.5 | 12.5 | 12.5 |
| Specialty Chemical) | | | | | |
| PBG-304 (Trony) | 0.5 | 0.5 | 0.5 | 0.5 | 0.5 |
| Propylene Glycol | 49 | 49 | 49 | 49 | 49 |
| Methyl Ether Acetate | | | | | |

The method for preparing a negative pixel defining layer (PDL) using the photosensitive compositions is as follows.

### (1) Application and Coating Step

A coating film is formed by removing a portion of the solvent using vacuum chamber dry (VCD) after applying a photosensitive composition to a certain thickness onto a substrate on which a washed 10 cm×10 cm metal has been deposited using a spin coater. The photosensitive composition is coated to a coating thickness of 2.0 μm to 1.7 μm after VCD to form the coating film.

### (2) Prebaking Step

In order to remove the solvent contained in the coating film obtained above, the film is heated on a hot plate at 80° C. to 120° C. for 50 seconds to 200 seconds. Since a certain amount of the solvent in the corresponding process is removed, it is possible to reduce contamination of a pixel-shaped mask and form a clean type pattern during the subsequent process (exposure step).

### (3) Exposure Step

After interposing a pixel-shaped mask to form a pattern required for the coating film obtained above and obtain a constant thickness, a pattern may be formed by irradiating an active ray of 190 nm to 600 nm, preferably a light source of a metal or LED lamp having a ghi-line through an exposure machine. The exposure amount irradiated for pattern formation is 20 mJ/cm² to 150 mJ/cm², and it is a negative-type photoresist material to be formed.

### (4) Development Step

Following the exposure step, when the coating film is developed by the dipping method in tetramethylammonium hydroxide (TMAH) as a developing solution at 23±2° C. for a certain period of time (minutes) and washed using ultrapure water (DI water), the non-exposed portion is dissolved and removed, thereby allowing only the part not exposed to light is dissolved and removed, leaving only the part exposed to light to thereby form an image pattern. The thickness of the residual coating is 1.70 μm to 1.90 μm.

### (5) Post-Baking Step

In order to obtain the image pattern obtained by the development, the solvent and the ultrapure water (DI water) absorbed to the coating film during the development step are completely removed by performing the post-baking step in an oven at 210° C. to 300° C. for 30 to 120 minutes, and cure the pattern thereby forming a film.

The present disclosure aims to implement a colored pattern with high optical density on an electrode substrate to not only make colors vivid but also increase the reliability and lifespan of a display. That is, the temperature for the post-baking treatment process is 210° C. to 300° C., and preferably 250° C. to 270° C. When the temperature is below 210° C., roughness increases, whereas when the temperature is above 300° C., the pattern formed film is thermally decomposed, thereby increasing roughness.

### (6) Measurement of Optical Density

After forming a pattern on a substrate through steps (1) to (5) using a photosensitive composition, the optical density was measured. After post-heat treatment, a film with a coating thickness of 1.45 μm to 1.55 μm was formed. After coating and post-baking treatment on a 10 cm×10 cm bare glass substrate with the photosensitive composition, the optical density of the substrate was measured using a 361T Transmission Densitometer (X-Rite Co., Ltd.). The samples were compared for optical density by average particle size of the inorganic pigments.

In the present disclosure, the optical density (OD) of the coating film after the post-baking treatment step is 2.0/μm or less, preferably 1.7/μm or less, and more preferably 1.5/μm or less.

### (7) Measurement of Particle Size

The pigment dispersions according to Preparation Examples 1 to 5 above were diluted 3,000 times in PGMEA solvent to prepare measurement samples, and the particle size was measured using SZ-100Z (HORIBA), respectively. During the measurement, D10, D50, and D90 values were obtained, and the average pigment size was defined as the overall mean value.

In the inorganic or organic pigment of the colorant used in the present disclosure, the mean value of D10 to D90 of particle size is 100 nm or less, preferably 90 nm or less, and more preferably 80 nm or less.

The present disclosure aims to implement a colored pattern with high optical density on an electrode substrate to not only make colors vivid but also increase the reliability and lifespan of the display. That is, when the particle size of the inorganic pigment exceeds 100 nm, residues may be generated after the development process, which may cause a decrease in luminance and a decrease in lifespan due to pixel shrinkage, whereas when the optical density is less than 0.8/μm, visibility and luminance are reduced. In addition, as the size of the inorganic pigment particles increases, the roughness of the surface also increases, and the adhesion in the post-process decreases when the size exceeds 2.5 nm. Therefore, it is very important to make the particle size of pigments to be 100 nm or less.

### (8) Measurement of Surface Roughness

As the samples for roughness measurement, the substrates for evaluation including a negative pixel defining layer formed through coating, exposure, development, and post-baking treatment with a composition including a colorant on a glass surface. The properties of the substrates for evaluation were measured using an atomic force microscope (AFM, Park Systems/XE-100), in a non-contact mode, at a scan rate of 0.3 (Hz), a set point (11.26 nm), and an area of 2 μm×2 μm.

In the present disclosure, the surface roughness (Ra) of the pixel defining layer is 3.0 nm or less, and preferably a film with an Ra of 2.7 nm or less, and more preferably 2.5 nm or less is formed.

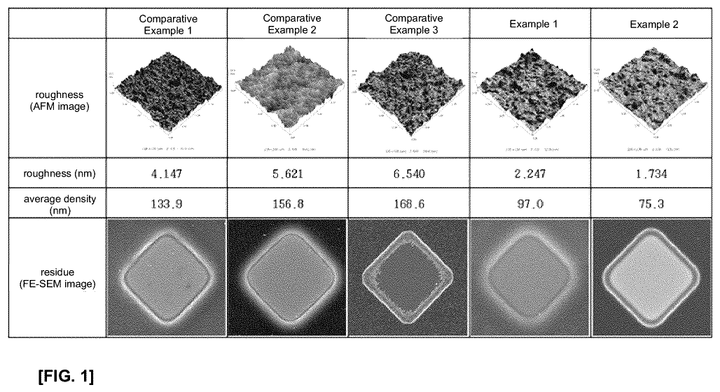

The measurement results are shown in Tables 2 and 3 below and FIG. 1.

TABLE 2

| Post-Baking | Comparative | Comparative | Comparative | | |
|---|---|---|---|---|---|
| Treatment | Example 1 | Example 2 | Example 3 | Example 1 | Example 2 |
| Process | (Preparation | (Preparation | (Preparation | (Preparation | (Preparation |
| (@ 250° C.) | Example 3) | Example 4) | Example 5) | Example 1) | Example 2) |
| Particle Size (D10) | 96.1 | 115.4 | 121.1 | 68.9 | 51.3 |
| Particle Size (D50) | 132.3 | 154.6 | 165.9 | 95.9 | 74.0 |
| Particle Size (D90) | 172.7 | 201.7 | 219.3 | 126.8 | 100.6 |
| Particle Size (Mean) | 133.9 | 156.8 | 168.6 | 97.0 | 75.3 |
| Optical Density (/μm) | 0.79 | 0.64 | 0.52 | 1.02 | 1.13 |
| Roughness (nm) | 4.147 | 5.621 | 6.540 | 2.247 | 1.734 |
| Residue | Yes | Yes | Yes | No | No |

TABLE 3

| Post-Baking | Comparative | Comparative | Comparative | Comparative | Comparative |
|---|---|---|---|---|---|
| Treatment | Example 4 | Example 5 | Example 6 | Example 7 | Example 8 |
| Process | (Preparation | (Preparation | (Preparation | (Preparation | (Preparation |
| (@ 180° C.) | Example 1) | Example 2) | Example 3) | Example 4) | Example 5) |
| Particle Size (D10) | 68.9 | 51.3 | 96.1 | 115.4 | 121.1 |
| Particle Size (D50) | 95.9 | 74.0 | 132.3 | 154.6 | 165.9 |
| Particle Size (D90) | 126.8 | 100.6 | 172.7 | 201.7 | 219.3 |
| Particle Size (Mean) | 97.0 | 75.3 | 133.9 | 156.8 | 168.6 |
| Optical Density (/μm) | 1.00 | 1.09 | 0.74 | 0.61 | 0.49 |
| Roughness (nm) | 2.403 | 2.056 | 4.343 | 5.748 | 6.692 |
| Residue | No | No | Yes | Yes | Yes |

The optical density and roughness of the substrate obtained in the process after the film formation and post-baking treatment steps of the photosensitive compositions using the pigment dispersions prepared in Preparation Examples 1 to 5 above were measured and compared.

Referring to Comparative Examples 1 to 3 of Table 2 above, it was confirmed that when the mean particle size was 120 nm or more, the optical density was 0.80/μm or less, and the roughness increased due to the particle size. In addition, it was confirmed that residues were generated when the development process was performed at the same time as the average particle size increased. Referring to Examples 1 and 2, it was confirmed that when the mean particle size was 100 nm or less, the optical density was 1.0/μm or more, the roughness was 2.5 nm or less, and there was no residue.

Referring to Comparative Examples 4 to 8 of Table 3 above, it was confirmed that when the temperature of the post-baking treatment step was lowered to 180° C., the optical density was slightly decreased compared to 250° C., whereas the roughness was increased.

Meanwhile, the pixel defining layer was prepared using the photosensitive compositions having the compositions shown in Table 4 below, and their respective optical density, sintering hardness, and modulus were measured.

TABLE 4

| | | | | Comparative | Comparative | Comparative | Comparative |
|---|---|---|---|---|---|---|---|
| | Example 3 | Example 4 | Example 5 | Example 9 | Example 10 | Example 11 | Example 12 |
| Black Pigment | 17.3 | 26.4 | 34.8 | 11.4 | 15.8 | 35.7 | 40 |
| Dispersion | | | | | | | |
| (Preparation | | | | | | | |
| Example 1) | | | | | | | |
| Cardo Binder | 15 | 15 | 15 | 15 | 15 | 15 | 15 |
| (Synthesis | | | | | | | |
| Example 2) | | | | | | | |
| Miramer M600 | 12.5 | 12.5 | 12.5 | 12.5 | 12.5 | 12.5 | 12.5 |
| (Miwon Specialty | | | | | | | |
| Chemical) | | | | | | | |
| PBG-304 (Tronly) | 0.5 | 0.5 | 0.5 | 0.5 | 0.5 | 0.5 | 0.5 |
| Propylene Glycol | 54.7 | 45.6 | 37.2 | 60.6 | 56.2 | 36.3 | 32 |
| Methyl Ether | | | | | | | |
| Acetate | | | | | | | |

### (9) Measurement of Optical Density

After forming a pattern on a substrate through the steps (1) to (5) using a photosensitive composition, the optical density was measured. After coating the photosensitive composition on a 10 cm×x 10 cm bare glass substrate and post-baking treatment, the optical density of the substrate was measured using a 361T Transmission Densitometer (X-Rite).

### (10) Measurement of Sintering Hardness and Modulus (Nanoindenter)

Substrates for evaluation were prepared for measuring sintering hardness and modulus, in which each substrate includes a negative pixel defining layer formed through coating, exposure, development, and post-baking treatment with a composition containing a colorant on a glass surface. The properties of the substrates for evaluation were measured using a nanoindenter (Fischer HM2000) under test force (0.2 mN), loading time (8 sec), and creep time (5 sec) conditions.

TABLE 5

| | | | | Comparative | Comparative | Comparative | Comparative |
|---|---|---|---|---|---|---|---|
| | Example 3 | Example 4 | Example 5 | Example 9 | Example 10 | Example 11 | Example 12 |
| Optical | 0.83 | 1.11 | 1.29 | 0.14 | 0.67 | 1.51 | 1.71 |
| Density/μm | | | | | | | |
| (@550 nm) | | | | | | | |
| Example | 411.46 | 442.31 | 456.24 | 281.34 | 351.58 | 467.68 | 470.35 |
| (N/mm²) | | | | | | | |
| Modulus | 6237.72 | 6383.24 | 6668.12 | 4618.9 | 5217.36 | 6731.44 | 6883.49 |
| (Mpa) | | | | | | | |
| Residue | ◯ | ◯ | ◯ | ◯ | ◯ | Δ | X |

The pixel patterns of the photosensitive compositions prepared in Examples 3 to 5 and Comparative Examples 9 to 12 were measured using an optical microscope to confirm the residue level. In Examples 3 to 5 and Comparative Examples 9 to 12, the content of the black pigment dispersion was shown to be 20 wt % or less, in which the residue level was shown to be excellent. In the cases of Comparative Examples 11 and 12, it was confirmed that as the content of the pigment dispersion was 20 wt % or more, the peripheral residue or the residue inside the pixel increased.

The sintering hardness and modulus according to optical density of the coating films of the photosensitive compositions prepared in Examples 3 to 5 and Comparative Examples 9 to 12 were measured and compared.

As shown in Table 5 above, in Comparative Examples 9 and 10, the mechanical properties were shown to be poor, with an optical density of 0.80/μm or less or a sintering hardness of 400 N/mm² or less. In addition, although it was very excellent in terms of residue, since the optical density was 0.80/μm or less, the visibility was poor, and due to the low sintering hardness, cracks may occur upon external impact.

Meanwhile, in the cases of Comparative Examples 11 and 12, it can be seen that residues were generated even though the optical density is 1.5/μm or more and the sintering hardness is 460 N/mm² or more.

In contrast, in the cases of Examples 3 to 5, it was found that the optical density was in the desirable range of 0.8/μm to 1.50/μm, the sintering hardness was in the range of 400 N/mm² to 467 N/mm², and the modulus was in the range of 6,200 Mpa to 6,670 Mpa, thus showing that it is excellent in terms of residue, and the visibility of the display is improved, thereby satisfying the conditions for the light-shieling layer and pixel defining layer.

The above description is merely illustrative of the present disclosure, and those skilled in the art to which the present disclosure pertains will be able to make various modifications without departing from the essential characteristics of the present disclosure.

Accordingly, the embodiments disclosed in this specification are for illustrative purposes only and are not intended to limit the present disclosure, and the spirit and scope of the present disclosure are not limited by these embodiments. The scope of protection of the present disclosure should be interpreted in accordance with the claims, and all technologies within the scope equivalent thereto should be interpreted as being included in the scope of rights of the present disclosure.

1. A method for preparing a pixel defining layer, comprising the steps of: applying and coating a photosensitive composition comprising a colorant having an average pigment particle size of 120 nm or less; performing prebaking; performing exposure; performing development; and performing post-baking treatment, wherein after the post-baking treatment step, the coating film has an optical density of 0.80/μm to 2.0/m, a sintering hardness of 350 N/mm² to 470 N/mm², a modulus of 5,200 Mpa to 6,800 Mpa, and a roughness of 3.0 nm or less, and has no residue.

2. The method of claim 1, wherein the temperature of the post-baking treatment step is 210° C. to 300° C.

3. The method of claim 1, wherein the temperature of the post-baking treatment step is 230° C. to 290° C.

4. The method of claim 1, wherein the post-baking treatment step is performed for 30 to 120 minutes.

5. The method of claim 1, wherein the post-baking treatment step is performed for 60 to 120 minutes.

6. The method of claim 1, wherein after the post-baking treatment step, the coating film has an optical density of 0.9/μm to 1.5/μm.

7. The method of claim 1, wherein after the post-baking treatment step, the coating film has a roughness of 2.5 nm or less.

8. The method of claim 1, wherein after the post-baking treatment step, the coating film has a sintering hardness of 410 N/mm² to 460 N/mm².

9. The method of claim 1, wherein after the post-baking treatment step, the coating film has a modulus of greater than 6,200 Mpa and equal to or less than 6,700 Mpa.

10. The method of claim 1, wherein the photosensitive composition comprises a colorant.

11. The method of claim 10, wherein the colorant comprises one or more among inorganic dyes, organic dyes, inorganic pigments, and organic pigments.

12. The method of claim 10, wherein the colorant is included in an amount of 17 wt % to 35 wt % based on the total amount of the photosensitive composition.

13. The method of claim 10, wherein the colorant is pretreated using a dispersant; or a water-soluble inorganic salt and a wetting agent.

14. The method of claim 1, wherein the photosensitive composition comprises a patterning resin which comprises an acrylic binder resin, a cardo-based binder resin, or a combination thereof.

15. The method of claim 14, wherein the acrylic binder resin has a weight average molecular weight of 3,000 g/mol to 150,000 g/mol.

16. The method of claim 14, wherein the cardo-based binder resin comprises a repeating structure of Formula 1 below: 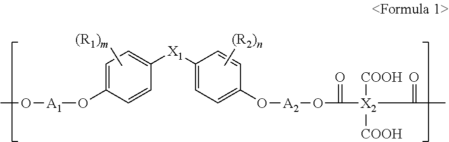
wherein in Formula 1 above,
1) R₁ and R₂ are each independently hydrogen; deuterium; a halogen; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
2) R₁ and R₂ can form a ring between neighboring groups,
3) m and n are each independently an integer of 0 to 4,
4) A₁ and A₂ are each independently Formula 2 or Formula 3 below, 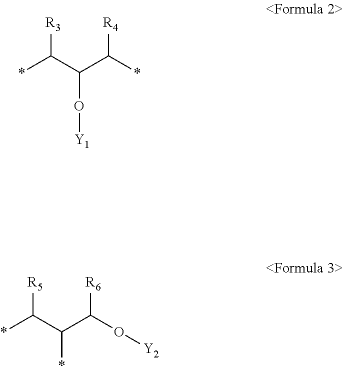
in Formula 2 and Formula 3,
4-1) * represents a connection part,
4-2) R₃ to R₆ are each independently hydrogen; deuterium; a halogen; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
4-3) R₃ to R₆ can form a ring between neighboring groups,
4-4) Y₁ and Y₂ are each independently Formula 6 or Formula 7 below: 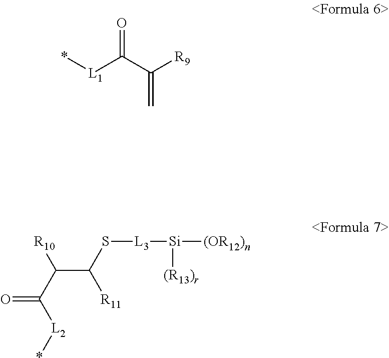
in Formula 6 and Formula 7 above,
4-4-1) * represents a binding position,
4-4-2) R₉ is hydrogen or methyl,
4-4-3) R₁₀ to R₁₃ are each independently hydrogen; deuterium; a halogen; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
4-4-4) L₁ to L₃ are each independently a single bond, a fluorenylene group; C₂₋₃₀ alkylene; C₆₋₃₀ arylene; a C₂₋₃₀ heterocyclic ring; C₁₋₃₀ alkoxylene, C₂₋₃₀ alkyleneoxy; C₆₋₃₀ aryloxy; or C₂₋₃₀ polyethyleneoxy,
4-4-5) q and r are each independently an integer of 0 to 3; with the proviso that q+r=3,
5) the ratio of A₁ and A₂ in the polymer chain of the resin including a repeating unit represented by Formula 1 is 9:1 to 1:9,
6) X₁ is a single bond; O; CO; SO2; CR′R″; SiR′R″; Formula 4 below; or Formula 5 below,
6-1) R′ and R″ are each independently hydrogen; deuterium; a halogen; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
6-2) R′ and R″ can form a ring between adjacent groups, 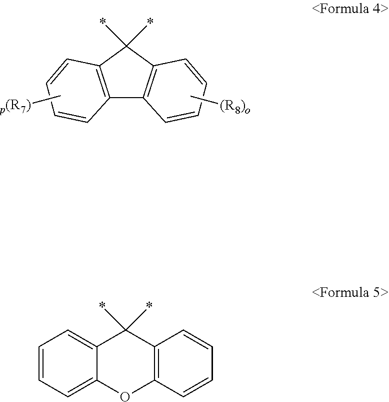
in Formula 4 and Formula 5 above,
6-3) * represents a binding position,
6-4) R₇ and R₈ are each independently hydrogen; deuterium; a halogen; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group,
6-5) o and p are each independently an integer of 0 to 4,
7) X₂ is a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a fluorenyl group; a carbonyl group; an ether group; or a C₁₋₂₀ alkoxycarbonyl group, and
8) the R′, R″, X₂, L₁ to L₃, R₁ to R₈, and R₁₀ to R₁₃ can each be further substituted with one or more substituents selected from the group consisting of deuterium; a halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group comprising at least one heteroatom among O, N, S, Si, and P; a C₃₋₃₀ alicyclic group; a C₇₋₃₀ arylalkyl group; a C₈₋₃₀ arylalkenyl group; and a combination thereof, or can form a ring between the neighboring substituents.

17. The method of claim 14, wherein the cardo-based resin has a average molecular weight of 1,000 g/mol to 100,000 g/mol.

18. The method of claim 14, wherein the cardo-based resin is included in an amount of 1 wt % to 30 wt % based on the total amount of the photosensitive composition.

19. The method of claim 1, wherein a reactive unsaturated compound is included in an amount of 1 wt % to 40 wt % based on the total amount of the photosensitive composition.

20. The method of claim 1, wherein a photoinitiator is included in an amount of 0.01 wt % to 10 wt % based on the total amount of the photosensitive composition.

21. A pixel defining layer prepared according to the method of claim 1.

22. An organic light-emitting display device comprising the pixel defining layer according to claim 21.

23. An electronic device comprising the display device of claim 22 and a control unit for operating the display device.
